(19) United States
(12) Patent Application Publication
(10) Pub. No.: US 2022/0028926 A1
(43) Pub. Date: Jan. 27, 2022

(54) Method for Producing a Radiation-Emitting Semiconductor Device and Radiation-Emitting Semiconductor Device

(71) Applicant: OSRAM Opto Semiconductors GmbH, Regensburg (DE)

(72) Inventor: Simeon Katz, Regensburg (DE)

(21) Appl. No.: 17/422,680

(22) PCT Filed: Jan. 10, 2020
(86) PCT No.: PCT/EP2020/050576

§ 371 Date: Jul. 13, 2021

(30) Foreign Application Priority Data
Jan. 21, 2019 (DE) 10 2019 101 417.4

(51) Int. Cl. H01L 27/15; H01L 25/18; H01L 25/00

(52) U.S. Cl. CPC H01L 27/156; H01L 25/50; H01L 25/18

(57) ABSTRACT

In an embodiment, a method for producing a radiation-emitting semiconductor device includes providing a carrier plate having contact elements, applying a radiation-emitting semiconductor chip to the carrier plate, epitaxially producing first conversion elements, epitaxially producing second conversion elements and applying the first conversion elements and the second conversion elements to the semiconductor chip, wherein the semiconductor chip includes emitter regions for emitting primary electromagnetic radiation from a radiation exit area, wherein the first conversion elements are simultaneously applied to at least some of the emitter regions after the epitaxial fabrication, and wherein the first conversion elements and the second conversion elements are arranged in a common plane.

This patent application is a national phase filing under section 371 of PCT/EP2020/050576, filed Jan. 10, 2020, which claims the priority of German patent application 102019101417.4, filed Jan. 21, 2019, each of which is incorporated herein by reference in its entirety.

### TECHNICAL FIELD

A method for producing a radiation-emitting semiconductor device and a radiation-emitting semiconductor device are specified.

### SUMMARY

Embodiments provide a method for producing a radiation-emitting semiconductor device which is particularly easy to produce. In addition, a radiation-emitting semiconductor device is to be provided which can be produced particularly inexpensively.

According to at least one embodiment, the method comprises providing a carrier plate comprising contact elements. The carrier plate has, for example, a main extension plane. Lateral directions are, for example, aligned parallel to the main extension plane and a vertical direction is aligned perpendicular to the lateral directions. The carrier plate has, for example, the shape of a disc or a cuboid.

The carrier plate comprises, for example, a base plate on which and/or in which the contact elements are arranged. The base plate comprises, for example, an electrically insulating material such as a plastic material, for example, an epoxy or a silicone, or a ceramic material, or consists of one of these materials. The contact elements arranged on the base plate are, for example, freely accessible from outside the carrier plate. The contact elements comprise or consist of, for example, a metal. The metal is or comprises for example gold, silver and/or copper. The contact elements can, for example, penetrate the base plate and/or be embedded in the base plate. “Embedded” can mean that the contact elements abut on the baseplate, are partially within the baseplate and/or are enclosed by the baseplate on at least a portion of its outer surface.

The carrier plate is or comprises, for example, a circuit board or a lead frame.

According to at least one embodiment of the method, a radiation-emitting semiconductor chip is applied to the carrier plate. The radiation-emitting semiconductor chip is configured, for example, to generate primary electromagnetic radiation during in operation, for example to generate near-ultraviolet radiation, visible light and/or near-infrared radiation.

For example, the radiation-emitting semiconductor chip comprises a semiconductor layer sequence having an active region. The active region is configured to generate primary electromagnetic radiation. For example, the active region has a pn junction for generating the primary electromagnetic radiation, such as a double heterostructure, a single quantum well structure or a multiple quantum well structure.

The semiconductor layer sequence is based, for example, on a III-V compound semiconductor material. The III-V compound semiconductor material is, for example, a phosphide, arsenide, and/or nitride compound semiconductor material, for example, InxAlyGa1-x-yP, InxAlyGa1-x-yAs, and/or InxAlyGa1-x-yN with 0≤x≤1, 0≤y≤1, and x+y≤1.

The semiconductor layer sequence can have dopants as well as additional components. For the sake of simplicity, however, only the essential constituents of the crystal lattice of the semiconductor layer sequence, i.e. Al, Ga, In, N, As or P, are indicated, even if these can be partially replaced and/or supplemented by small amounts of further substances.

For example, the semiconductor layer sequence of the semiconductor chip can be epitaxially generated on a growth wafer prior to deposition. The growth wafer comprises, for example, sapphire, glass, or semiconductor materials such as GaAs, GaP, GaSb, Ge or Si. For example, the growth wafer can be detached after the semiconductor chip is deposited on the carrier plate.

Further, the radiation-emitting semiconductor chip can comprise chip contact areas, which comprise a metal or consist of a metal, for example. At least two chip contact areas are associated with each emitter region, for example, with which the associated emitter region can be supplied with current. One of the chip contact areas can also be assigned to several emitter regions or all emitter regions, for example. The chip contact areas can be applied to the contact elements, for example, by bonding, adhesion or soldering. For example, the chip contact areas are mechanically and/or electrically conductively connected to the contact elements during application. This connection fixes the semiconductor chip to the carrier plate.

According to at least one embodiment of the method, first conversion elements are produced epitaxially. The first conversion elements each comprise, for example, a first semiconductor layer stack which has a further first active region. The further first active region is adapted to partially absorb primary electromagnetic radiation and to re-emit it as first secondary electromagnetic radiation. For example, the further first active region can comprise a pn junction, such as a double heterostructure, a single quantum well structure or a multiple quantum well structure.

For example, a peak wavelength of the first secondary electromagnetic radiation is greater than a peak wavelength of the primary electromagnetic radiation.

The first semiconductor layer stacks can each be produced by an epitaxial process, i.e. by epitaxial growth on a first growth substrate. For example, the semiconductor layer stacks in the form of a further first semiconductor layer sequence can be produced over a large area by means of metal organic vapour phase epitaxy (MOVPE) or molecular beam epitaxy (MBE).

The further first semiconductor layer sequence is based, for example, on a III-V compound semiconductor material. The III-V compound semiconductor material is, for example, a phosphide, arsenide and/or nitride compound semiconductor material, i.e., for example, InₓAl_{y}Ga_{1-x-y}P, InₓAl_{y}Ga_{1-x-y}As and/or InₓAl_{y}Ga_{1-x-y}N with 0≤x≤1, 0≤y≤1 and x+y≤1. Furthermore, the further first semiconductor layer sequence can be partially replaced and/or supplemented by small amounts of further substances.

After the further first semiconductor layer sequence is produced, the further first semiconductor layer sequence can be detached from the first growth substrate. Furthermore, it is possible that the further first semiconductor layer sequence is separated before or after the detachment to form the first semiconductor layer stacks and thus the first conversion elements. The further first semiconductor layer sequence is separated to form the first conversion elements, for example, by means of a sawing process, a punching process or a laser process.

According to at least one embodiment of the method, the first conversion elements are applied to the semiconductor chip. The first conversion elements are applied to the semiconductor chip, for example, by means of a first device. The depositing comprises in particular a mechanical fastening of the first conversion elements on the semiconductor chip.

According to at least one embodiment of the method, the semiconductor chip comprises emitter regions each emitting primary electromagnetic radiation from a radiation exit area. For example, each emitter region is associated with a radiation exit area. The emitter regions are the radiation-emitting components of the semiconductor chip. The emitter regions can be operated independently of one another, for example, so that it is possible to operate exactly one emitter region, several emitter regions or all emitter regions of the semiconductor chip at the same times.

Each emitter region can be operated with an individual current intensity. This makes it possible, for example, for the emitter regions to emit different brightness. For example, all emitter regions are part of the same radiation-emitting semiconductor chip. In this case, the semiconductor chip is a pixelated semiconductor chip structured into separately drivable regions, each region forming an emitter region, for example. The emitter regions of such a radiation-emitting semiconductor chip are, for example, fabricated together on the common growth wafer and comprise an active region in which electromagnetic primary radiation is generated during operation and which has the same composition within the fabrication tolerance for all emitter regions of the semiconductor chip. It is possible, for example, that all emitter regions of the semiconductor chip are mechanically and electrically connected to one another via a common, epitaxially produced semiconductor layer of the semiconductor layer sequence.

Each emitter region emits, for example, electromagnetic primary radiation from the associated radiation exit area. The radiation exit areas of the emitter regions are preferably formed by a top surface of the respective emitter regions. Preferably, at least 70% of the primary radiation emitted by the emitter regions exits through the respective radiation exit area.

According to at least one embodiment of the method, the first conversion elements are simultaneously applied to at least some of the emitter regions the after epitaxial fabrication. For example, the first conversion elements can be applied simultaneously to at least some of the emitter regions by means of a first device. For example, the first conversion elements are not applied to all of the emitter regions. In this case, the radiation-emitting semiconductor device comprises emitter regions on which no first conversion element is arranged.

In at least one embodiment, the method for producing a radiation-emitting semiconductor device comprises the steps of: providing a carrier plate comprising contact elements, applying a radiation-emitting semiconductor chip on the carrier plate, epitaxially producing first conversion elements, and applying the first conversion elements to the semiconductor chip,

wherein the semiconductor chip comprises emitter regions each emitting primary electromagnetic radiation from a radiation exit area, and wherein the first conversion elements are simultaneously applied to at least some of the emitter regions after epitaxial fabrication.

One idea of the method described here for producing a radiation-emitting device is, among other things, that conversion elements are simultaneously applied in already separated form to a pixelated semiconductor chip. With such a pixelated semiconductor chip, it is possible to arrange the emitter regions particularly close to one another, since the emitter regions are not placed individually on a carrier, but are created by structuring a larger structure, for example, a semiconductor wafer. As a result, the semiconductor chip and thus the radiation-emitting device can be formed in a particularly space-saving manner.

According to at least one embodiment of the method, second conversion elements are produced epitaxially. The second conversion elements each comprise, for example, a second semiconductor layer stack which has a further second active region. The further second active region is configured to partially absorb primary electromagnetic radiation and to re-emit it as second secondary electromagnetic radiation. For example, the further second active region can comprise a pn junction, such as a double heterostructure, a single quantum well structure or a multiple quantum well structure.

The second semiconductor layer stacks can each be formed, for example, by an epitaxial process, i.e. by epitaxial growth on a second growth substrate. For example, the semiconductor layer stacks in the form of a further second semiconductor layer sequence can be produced over a large area by means of metal organic vapour phase epitaxy (MOVPE) or molecular beam epitaxy (MBE).

The further second semiconductor layer sequence is based, for example, on a III-V compound semiconductor material. The III-V compound semiconductor material is, for example, a phosphide, arsenide and/or nitride compound semiconductor material, i.e., for example, InₓAl_{y}Ga_{1-x-y}P, InₓAl_{y}Ga_{1-x-y}As and/or InₓAl_{y}Ga_{1-x-y}N with 0≤x≤1, 0≤y≤1 and x+y≤1. Furthermore, the further second semiconductor layer sequence can be partially replaced and/or supplemented by small amounts of further substances.

After the further second semiconductor layer sequence has been generated, the further second semiconductor layer sequence can be detached from the second growth substrate. Furthermore, it is possible that the further first semiconductor layer sequence is separated before or after the detachment to form the second semiconductor layer stacks and thus the second conversion elements. The further second semiconductor layer sequence is separated to form the second conversion elements, for example, by means of a sawing process, a punching process or a laser process.

A peak wavelength of the second electromagnetic secondary radiation is in particular greater than a peak wavelength of the electromagnetic primary radiation. Further, the first secondary radiation of the first conversion elements and the second secondary radiation of the second conversion elements are, for example, different from one another. For example, the first conversion elements are adapted to convert all or part of blue light into green or yellow light. Further, the second conversion elements can be adapted to convert blue light completely or partially into red, yellow or green light. In this case, the primary electromagnetic radiation is, for example, blue light.

For example, it is possible that the first conversion elements and/or the second conversion elements are arranged to convert the primary electromagnetic radiation as completely as possible into first secondary radiation and/or second secondary radiation.

According to at least one embodiment of the method, the second conversion elements are applied to the semiconductor chip. For example, the second conversion elements are applied to the semiconductor chip by means of a second device.

According to at least one embodiment of the method, the second conversion elements are simultaneously applied to at least some of the emitter regions the after epitaxial fabrication. For example, the second conversion elements can be applied simultaneously to at least some of the emitter regions by means of a second device. For example, the second conversion elements are not applied to all of the emitter regions. In this case, the radiation-emitting semiconductor device comprises emitter regions on which no second conversion element is arranged.

For example, the first conversion elements and the second conversion elements are applied to the semiconductor chip spaced apart in lateral directions. In this case, the first conversion elements and the second conversion elements do not overlap in plan view, for example.

According to at least one embodiment of the method, the first conversion elements and the second conversion elements are arranged in a common plane. For example, the first conversion elements each comprise a top surface and an opposite bottom surface. Furthermore, the second conversion elements also each have a top surface and an opposite bottom surface. For example, the top surfaces of the first conversion elements and the top surfaces of the second conversion elements lie in a common plane that extends in lateral directions. Further, the bottom surfaces of the first conversion elements and the bottom surfaces of the second conversion elements lie, for example, in a common plane extending in lateral directions. In this case, the first conversion elements and the second conversion elements overlap substantially completely in a side view along a lateral direction, for example. Substantially completely means that the first conversion elements and the second conversion elements can have variations in their height due to conditional of manufacturing.

Advantageously, the arrangement of the conversion elements in one plane suppresses crosstalk of primary radiation and/or secondary radiation between adjacent conversion elements. Thus, primary radiation and/or secondary radiation emerging from the cover surface of the conversion elements advantageously do not impinge or rarely impinge on an adjacent conversion element.

According to at least one embodiment of the method, the radiation exit areas are arranged at grid points of a regular grid. In other words, the emitter regions are arranged at grid points of a regular grid. Thus, for example, the radiation exit areas are arranged in a matrix-like manner, that is, along columns and rows. The regular grid is for example a triangular grid, a square grid or a hexagonal grid.

Alternatively, the radiation exit areas are arranged at grid points of an irregular grid. For example, the grid points of the regular grid or the irregular grid extend in lateral directions.

Further, the first conversion elements can be partially arranged at the grid points of the regular lattice at the radiation exit areas. Additionally, the second conversion elements can be partially arranged at grid points of the regular lattice not occupied by the first conversion elements at the radiation exit areas.

According to at least one embodiment of the method, a respective recess is generated in the semiconductor chip in the respective emitter region before the conversion elements are applied. The recesses are generated, for example, by means of material removal of the semiconductor layer sequence. Furthermore, the recesses are spaced apart from one another in lateral directions.

For example, the semiconductor layer sequence is only partially removed in vertical direction. For example, the recesses do not completely penetrate the semiconductor layer sequence. For example, the recesses penetrate the semiconductor layer sequence in vertical direction in such a way that the active region of the emitter regions is not penetrated. For example, a depth of the recess is equal to a height of the conversion elements. Further, a length and a width of the recesses are greater than the extents of the conversion elements in lateral directions, for example at least 1% greater, but at most 10% greater or at most 5% greater.

For example, the recesses in the semiconductor layer sequence each have a depth in the vertical direction of from 1 μm to 10 μm inclusive. Furthermore, the recesses have, for example, extent in lateral directions of at least 3 μm and at most 50 μm.

The recesses are generated, for example, by material removal by means of a chemical etching process or a laser ablation process.

According to at least one embodiment of the method, the first conversion elements are introduced into at least some of the recesses. For example, the first conversion elements are not introduced into all of the recesses. In this case, the radiation-emitting semiconductor device comprises emitter regions on which no first conversion element is arranged.

For example, the conversion elements are introduced in the recesses such that the top surfaces of the first conversion elements do not protrude beyond the recesses. Alternatively, it is possible that the top surfaces of the first conversion elements project beyond the recesses in vertical direction.

According to at least one embodiment, the second conversion elements are introduced into at least some of the recesses. For example, the second conversion elements are not introduced into all of the recesses. In this case, the radiation-emitting semiconductor device comprises emitter regions on which no second conversion element is arranged.

Furthermore, it is possible that a reflective layer is applied to the side surfaces of the recesses before the conversion elements are introduced. Advantageously, crosstalk of primary radiation and/or secondary radiation between adjacent conversion elements can thus be suppressed.

According to at least one embodiment of the method, an adhesion promoting layer is applied to the emitter regions before the conversion elements are applied. For example, the conversion elements are fixed to the radiation exit areas of the emitter regions. For example, the adhesion promoter is then arranged between the conversion elements and the radiation-emitting semiconductor chip. The adhesion promoter mediates a connection between the conversion elements and the radiation-emitting semiconductor chip. This connection fixes the conversion elements to the radiation-emitting semiconductor chip in a mechanically stable manner, for example.

The adhesion promoter comprises or consists of, for example, a radiation-transmissive material. For example, the material of the adhesion promoter is adapted to transmit primary electromagnetic radiation and/or secondary electromagnetic radiation. For example, the adhesion promoter transmits at least 90% of the primary electromagnetic radiation and/or secondary electromagnetic radiation. The adhesion promoter thus also serves to optically connect the conversion elements to the radiation-emitting semiconductor chip.

The adhesion promoter can comprise a resin, such as an epoxy or a silicone. For example, the material of the adhesion promoter is in a flowable form when applied. For example, the material of the adhesion promoter is sprayed up. For example, the material of the adhesion promoter is cured after application of the first conversion elements to the adhesion promoter.

According to at least one embodiment of the method, three emitter regions form a subpixel group. The emitter regions of the subpixel group can, for example, be arranged along a row or a column. Furthermore, it is possible that the three emitter regions are arranged in the form of a triangle. The light emitted from the emitter regions of the subpixel group can mix to form mixed light. For example, the subpixel group emits visible light.

According to at least one embodiment of the method, a first conversion element is arranged over a first radiation exit area of one of the three emitter regions. In this case, the first conversion element converts, for example, blue light into green light.

According to at least one embodiment of the method, a second conversion element is arranged over a second radiation exit area of one of the three emitter regions. In this case, the second conversion element is configured to convert, for example, blue light into red light.

According to at least one embodiment of the method, a third radiation exit area of one of the three emitter regions is free of a conversion element. In the event that the emitter region free of a conversion element emits blue light, the blue light is coupled out of the radiation-emitting semiconductor device unconverted via the third radiation exit area. Outside the radiation-emitting semiconductor device, the primary radiation, the first secondary radiation and the second secondary radiation can be mixed to form mixed light.

According to at least one embodiment of the method, the semiconductor chip comprises a plurality of subpixel groups. For example, the subpixel groups are arranged at grid points of a regular grid. For example, the subpixel groups are arranged in a matrix-like manner, that is, along columns and rows.

According to at least one embodiment of the method, the carrier plate comprises electronic control elements. For example, each emitter region can have its own control element associated therewith. Alternatively, it is possible that several emitter regions are assigned to one control element or that a single control element is assigned to all emitter regions.

According to at least one embodiment of the method, the control elements comprise an integrated circuitry. For example, each control element can comprise an integrated circuitry. Alternatively, it is possible that several control elements comprise an integrated circuitry or that all control elements are formed by an integrated circuitry.

For example, the integrated circuitry is formed by or comprises an integrated circuit (IC). The integrated circuit comprises, for example, a control unit. The control unit can, for example, control the state of an associated emitter region and, for example, switch it on or off. Furthermore, by means of the control unit, the current intensity by means of which an associated emitter region is operated can be predetermined.

According to at least one embodiment of the method, the emitter regions can be controlled separately from one another. Thus, each emitter region of a subpixel group can be controlled individually. Furthermore, the subpixel groups can be operated individually. In this case, the radiation-emitting semiconductor device can be a display.

According to at least one embodiment of the method, the first conversion elements are applied simultaneously by means of a first die. The separated first conversion elements are arranged, for example, on the first die. The first die can subsequently be positioned over the semiconductor chip and pressed with a constant pressure onto the radiation exit areas of the semiconductor chip. The first conversion elements can then be detached from the first die, for example by means of a heating step, so that the first conversion elements remain on the semiconductor chip.

According to at least one embodiment of the method, the second conversion elements are applied simultaneously by means of a second die. For example, the separated second conversion elements can be arranged on the second die. Before or after the step of applying the first conversion elements, the second conversion elements can be applied on the semiconductor chip as described analogously for applying the first conversion elements by means of a first die.

According to at least one embodiment of the method, the first die is different from a growth substrate of the first conversion elements. For example, the first die comprises or is formed from a polymer. For example, the polymer is polydimethylsiloxane (PDMS).

According to at least one embodiment of the method, the second die is different from a growth substrate of the second conversion elements. For example, the second die comprises the same materials as the first die or comprises the same materials.

By using the first and the second die, the conversion elements can be applied to the semiconductor chip in a particularly efficient and time-saving manner. Furthermore, different conversion element positions on the semiconductor chip can advantageously be predetermined by a simple adaptation of the die structure.

Furthermore, the first and second die can be used to equip a plurality of semiconductor chips with first and second conversion elements.

Furthermore, a radiation-emitting device that can be produced, in particular, by a method for producing a radiation-emitting device described herein is specified. All features and embodiments disclosed in connection with the method are therefore also disclosed in connection with the radiation-emitting semiconductor device, and vice versa.

According to at least one embodiment, the radiation-emitting semiconductor device comprises a carrier plate having contact elements.

According to at least one embodiment, the radiation-emitting semiconductor device comprises a radiation-emitting semiconductor chip arranged on the carrier plate.

According to at least one embodiment, the radiation-emitting semiconductor device comprises first conversion elements arranged on the semiconductor chip.

According to at least one embodiment, the radiation-emitting semiconductor device comprises second conversion elements arranged on the semiconductor chip.

According to at least one embodiment, the radiation-emitting semiconductor chip comprises emitter regions each emitting primary electromagnetic radiation from an associated radiation exit area.

According to at least one embodiment, the first conversion elements and the second conversion elements are formed of a semiconductor material.

According to at least one embodiment, the first conversion elements and the second conversion elements are arranged in a common plane.

According to at least one embodiment, the conversion elements are epitaxial conversion elements.

According to at least one embodiment, the emitter regions each have lateral extent between 3 μm and 50 μm inclusive. For example, the radiation exit areas can also each have a lateral extent between 3 μm and 50 μm inclusive. Further, it is possible that the conversion elements each have lateral extent between 3 μm and 50 μm, inclusive. For example, it is possible that the lateral extents of the emitter regions, the radiation exit areas and/or the conversion elements are each between 5 μm and 10 μm inclusive.

According to at least one embodiment, the conversion elements each have a vertical extent between 1 μm and 10 μm, inclusive. For example, the vertical extents of the conversion elements are each between 3 μm and 5 μm, inclusive.

### BRIEF DESCRIPTION OF DRAWINGS

In the following, the method described herein as well as the radiation-emitting device described herein will be explained in more detail with reference to exemplary embodiments and the associated Figures.

FIGS. 1, 2 and 3 show schematic sectional views of method stages in the production of a radiation-emitting semiconductor device according to an exemplary embodiment;

FIG. 4 shows schematic sectional views of a radiation-emitting semiconductor device according to an exemplary embodiment; and

FIGS. 5 and 6 show schematic sectional views of a radiation-emitting semiconductor chip each according to an exemplary embodiment.

Elements that are identical, similar or similar acting are given the same reference signs in the Figures. The Figures and the proportions of the elements shown in the Figures are not to be regarded as true to scale. Rather, individual elements can be shown exaggeratedly large for better representability and/or for better comprehensibility.

### DETAILED DESCRIPTION OF ILLUSTRATIVE EMBODIMENTS

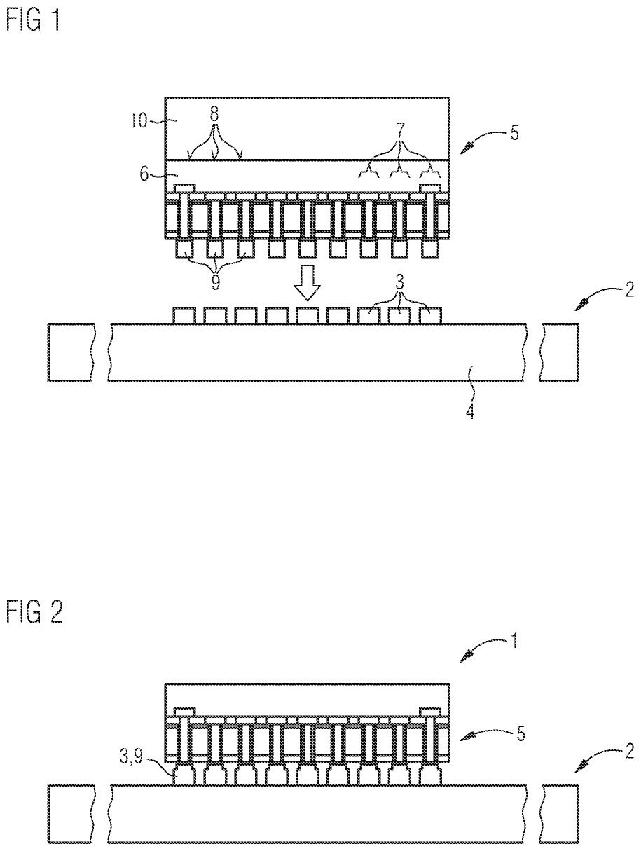

The schematic sectional views of FIGS. 1, 2 and 3 show method steps of an exemplary embodiment of a method described herein for producing a radiation-emitting semiconductor device 1.

First, a carrier plate 2 is provided. The carrier plate 2 comprises a base plate 4 on which contact elements 3 are arranged. The contact elements 3 arranged on the base plate 3 are exposed from the outside. The carrier plate 2 is or comprises, for example, a printed circuit board (PCB) or a lead frame. A maximum extent of the carrier plate 2 in lateral directions is, for example, between 20 cm and 25 cm.

According to FIG. 1, a radiation-emitting semiconductor chip 3 is applied to the carrier plate 2. The semiconductor chip 3 comprises emitter regions 7, each of which emits electromagnetic primary radiation from a radiation exit area 8. Each emitter region 7 is associated with a radiation exit area 8. The semiconductor chip 3 comprises a semiconductor layer sequence 6 arranged on a growth wafer 10.

Furthermore, the semiconductor chip 6 comprises chip contact areas 9. For example, two chip contact areas 9 are assigned to each emitter region, with which the assigned emitter region 7 can be supplied with current.

According to FIG. 2, the semiconductor chip 6 is applied to the carrier plate 2. The chip contact areas 9 can be applied to the contact elements 3, for example, by gluing, bonding or soldering. After application, the chip contact areas 9 are in mechanical and/or electrical conductive contact with the contact elements 3. This connection fixes the semiconductor chip 5 to the carrier plate 2.

Furthermore, the growth wafer 10 according to FIG. 2 can be detached from the semiconductor layer sequence 6 in a further method step.

In a further method step, first conversion elements 11 and second conversion elements 12 are produced epitaxially (not shown here). The separated first conversion elements 11 can then be arranged on a first die 13 and simultaneously transferred to the semiconductor chip 5. Furthermore, the second conversion elements 12 can be arranged on a second die 14 as shown in FIG. 3. By means of the second die 14, the conversion elements 12 can be applied together and thus simultaneously to the semiconductor chip 5. The second die 14 with the second conversion elements 12 is positioned, for example, above the semiconductor chip 5 and is pressed with a constant pressure onto the radiation exit areas 8 of the semiconductor chip 5. The second conversion elements 12 can then be detached from the second die 14, for example by means of a heating step, so that the second conversion elements 12 remain on the semiconductor chip 5.

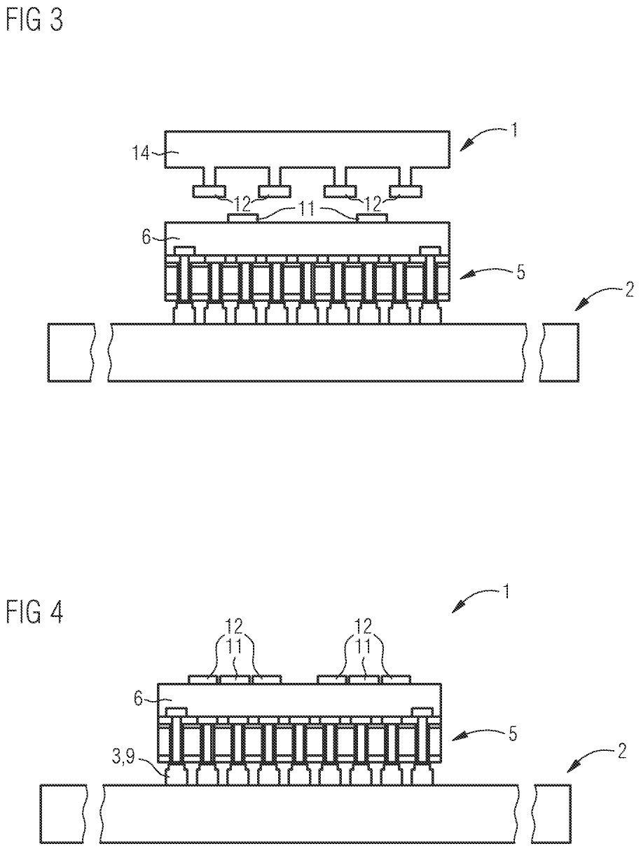

The schematic sectional view of FIG. 4 shows an exemplary embodiment of a radiation-emitting semiconductor device 1 described herein.

The radiation-emitting semiconductor device 1 is produced, for example, using the method steps according to FIGS. 1 to 3.

The first conversion elements 11 and the second conversion elements 12 are arranged in a common plane. The first conversion elements 11 and the second conversion elements 12 each have a top surface and an opposite bottom surface. The top surfaces of the first conversion elements 11 and the top surfaces of the second conversion elements 12 lie in a common plane. Furthermore, the bottom surfaces of the first conversion elements 11 and the bottom surfaces of the second conversion elements 12 lie in a common plane. The first conversion elements 11 and the second conversion elements 12 substantially completely overlap in a side view along a row and/or column. Substantially completely means that the first conversion elements 11 and the second conversion elements 12 can have variations in their height due to conditional of manufacturing.

For example, the emitter regions 7 are configured to emit blue light. In this case, the first conversion elements 11 are configured to convert blue light completely or partially into green or yellow light. Furthermore, the second conversion elements in this case are configured to convert blue light completely or partially into red light.

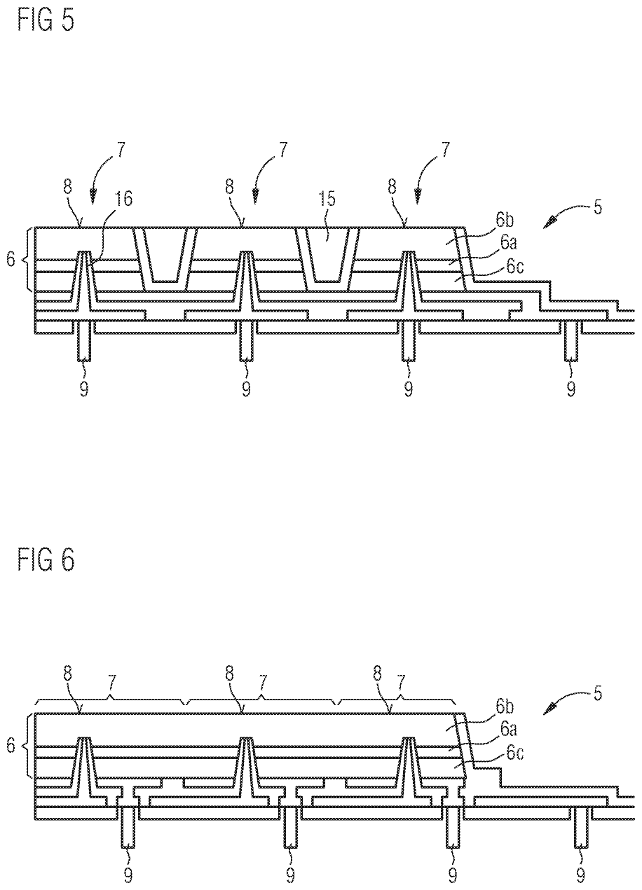

FIG. 5 shows an exemplary embodiment of a radiation-emitting semiconductor chip 5 in which emitter regions 7 are integrated into a semiconductor chip 5.

The semiconductor chip 5 has an epitaxially deposited semiconductor layer sequence 6 with an active region 6a provided for generating radiation, wherein the active region 6a is arranged between a first semiconductor layer 6b of a first conduction type, for example n-conducting, and a second semiconductor layer 6c of a second conduction type, for example p-conducting, different from the first conduction type.

The individual emitter regions 7, in particular the active regions 6a of these emitter regions 7, each emerge from a partial region of the semiconductor layer sequence 6.

In particular, these partial regions are formed from the same semiconductor layer sequence during the production of the semiconductor chip, so that the semiconductor layers of the individual emitter regions 7 do not differ in terms of their material and layer thickness apart from lateral variations due to conditional of manufacturing.

The emitter regions 7 are separated from one another by interspaces 15. In particular, the interspaces 15 severe the active regions 6a of adjacent emitter regions 7. For example, the interspaces 15 severe the entire semiconductor layer sequence 6 in vertical direction.

The first semiconductor layer 6b is electrically conductively connected to an associated chip contact area 9 by means of openings 16 in each case. The openings 16 extend through the second semiconductor layer 6c and the active region 6a. The second semiconductor layers 6c of the emitter regions 7 are electrically conductively connected to one another and can be at the same electrical potential during operation of the semiconductor chip 5. Both sides of the active region 6a are accessible for electrical contacting. Of course, the electrical contacting of the individual emitter regions 7 can be varied within wide limits as long as the individual emitter regions 7 can be controlled individually and, during operation of the semiconductor chip 5, charge carriers from opposite sides can enter the active region 6a and recombine there, emitting radiation.

The exemplary embodiment for a semiconductor chip 5 described in FIG. 6 corresponds substantially to the exemplary embodiment described in connection with FIG. 5. In contrast, the semiconductor layer sequence 6 in the exemplary embodiment shown in FIG. 6 is not separated between adjacent emitter regions 7. The spatial separation between adjacent emitter regions 7 thus results substantially from the limited lateral current expansion during the electrical contacting of the individual emitter regions 7. In the exemplary embodiment shown, the spatial extent of the chip contact area 16 to the second semiconductor layer 6c determines the lateral extent of the radiation emission of an emitter region 7.

The invention is not limited to the exemplary embodiments by the description based thereon. Rather, the invention encompasses any new feature as well as any combination of features, which in particular includes any combination of features in the claims, even if this feature or combination itself is not explicitly indicated in the claims or exemplary embodiments.

1.-15. (canceled)

16. A method for producing a radiation-emitting semiconductor device, the method comprising:
providing a carrier plate having contact elements;
applying a radiation-emitting semiconductor chip to the carrier plate;
epitaxially producing first conversion elements;
epitaxially producing second conversion elements; and
applying the first conversion elements and the second conversion elements to the semiconductor chip,
wherein the semiconductor chip comprises emitter regions for emitting primary electromagnetic radiation from a radiation exit area,
wherein the first conversion elements are simultaneously applied to at least some of the emitter regions after the epitaxial fabrication, and
wherein the first conversion elements and the second conversion elements are arranged in a common plane.

17. The method according to claim 16, wherein the second conversion elements are simultaneously applied to at least some of the emitter regions after the epitaxial fabrication.

18. The method according to claim 16, wherein the radiation exit areas are arranged at grid points of a regular grid.

19. The method according to claim 16,
wherein prior to applying the conversion elements, recesses are generated in the semiconductor chip in the emitter regions,
wherein the first conversion elements are introduced into at least some of the recesses, and
wherein the second conversion elements are introduced into at least some of the recesses.

20. The method according to claim 16, further comprising applying an adhesion promoting layer to the emitter regions before applying the conversion elements.

21. The method according to claim 16,
wherein three emitter regions form a subpixel group,
wherein a first conversion element is arranged over a first radiation exit area of one of the three emitter regions,
wherein a second conversion element is arranged over a second radiation exit area of one of the three emitter regions, and
wherein a third radiation exit area of one of the three emitter regions is free of a conversion element.

22. The method according to claim 21, wherein the semiconductor chip comprises a plurality of sub-pixel groups.

23. The method according to claim 16,
wherein the carrier plate comprises electronic control elements, and
wherein the control elements comprise an integrated circuitry.

24. The method according to claim 16, wherein the emitter regions are separately controllable from one another.

25. The method according to claim 16,
wherein the first conversion elements are applied simultaneously by a first die,
wherein the second conversion elements are applied simultaneously by a second die,
wherein the first die is different from a growth substrate of the first conversion elements, and
wherein the second die is different from a growth substrate of the second conversion elements.

26. A radiation-emitting semiconductor device comprising:
a carrier plate having contact elements;
a radiation-emitting semiconductor chip arranged on the carrier plate;
first conversion elements arranged on the semiconductor chip; and
second conversion elements arranged on the semiconductor chip,
wherein the semiconductor chip comprises emitter regions, each emitter region configured to emit primary electromagnetic radiation from a radiation exit area,
wherein the first conversion elements and the second conversion elements are formed of a semiconductor material,
wherein the first conversion elements and the second conversion elements are arranged in a common plane, and
wherein the conversion elements are epitaxial conversion elements.

27. The radiation-emitting semiconductor device according to claim 26, wherein each of the emitter regions has a lateral extent between 3 μm and 50 μm inclusive.

28. The radiation-emitting semiconductor device according to claim 27, wherein each of the conversion elements has a vertical extent between 1 μm and 10 μm inclusive.
